(19) United States
(12) Patent Application Publication
(10) Pub. No.: US 2017/0192157 A1
(43) Pub. Date: Jul. 6, 2017

(54) METAL-DOPED QUANTUM DOT, LED DEVICE AND BACKLIGHT MODULE

(71) Applicants: Shenzhen China Star Optoelectronics Technology Co. Ltd., Shenzhen, Guangdong (CN); Wuhan China Star Optoelectronics Technology Co., Ltd., Wuhan, Hubei (CN)

(72) Inventor: Yan CHENG, Guangdong (CN)

(21) Appl. No.: 14/892,080

(22) PCT Filed: Sep. 11, 2015
(86) PCT No.: PCT/CN2015/089474

§ 371 Date: Nov. 18, 2015

(30) Foreign Application Priority Data
Aug. 17, 2015 (CN) 201510505342.3

(51) Int. Cl. F21V 8/00; H01L 27/15; H01L 33/00; H01L 33/60; H01L 33/06; H01L 33/26

(52) U.S. Cl. CPC G02B 6/0073; H01L 33/06; H01L 33/26; H01L 33/005; H01L 33/60; H01L 27/153; G02B 6/009

(57) ABSTRACT

A metal-doped quantum dot is provided. By doping metal in the intrinsic quantum dot, the quantum dot has fluorescent stability and may not be quenched at high temperature. Meanwhile, the metal-doped quantum dot is used to prepare red, green and blue quantum dot dielectric layers, and the red, green and blue quantum dot dielectric layers are packaged in a LED device to mix the red, green and blue light to obtain a white light. In addition, the above LED device can be used to prepare a LED bar with simple structure which is adapt for a side-incident backlight module and good for designing ultra-thin and narrow bezel product.

### TECHNICAL FIELD

The present disclosure relates a quantum dot and backlight technical field, in particular to a metal-doped quantum dot and a LED device and a backlight module prepared using the same.

### BACKGROUND ART

The backlight module, as an important component of a liquid crystal display, provides a light source to the liquid crystal display, and its lighting effect determines color appearance on the display. So far, light sources in the backlight module in the market are mainly divided into two types of cold cathode fluorescent lame (CCFL) and light emitting diode (LED). LED has a significant advantages over energy conservation and environment protection, material volume and service life, thus it gradually replace CCFL to be a backlight source for the liquid crystal display.

However, with respect to the normal white LED, its color gamut level is only at about 72% and even lower, which is greatly bad for color appearance of the liquid crystal display. In order to improve the color gamut, quantum dot backlight source technology emerges as the times require. In the use of the quantum dot technology, the general approach is using the photoluminescence of the quantum dot, that is, a normal white LED (the main light emitted from this light source is blue light) is used to excite red and green quantum dot fluorescences and mix the light of the three colors to form white light, thereby improving the color gamut of the display to be 100%. The key to the approach is light conversion efficiency of the quantum dot, which directly affects the consumption of the quantum dots, and also indirectly affects the economic cost of the display.

Patent document CN103487857A discloses a quantum dot film and a backlight module, wherein a quantum dot layer in the quantum dot film includes a matrix, quantum dots and diffusion particles which are uniformly dispersed in the matrix, and the diffusion particles scatter the incident rays, thus an optical path through which the rays pass the quantum dot layer is increased, the quantum dot utilization rate is increased, and the light conversion efficiency is improved.

Patent document CN103852817A discloses a quantum dot film applied to a backlight module, wherein the quantum dot film includes a quantum dot layer, and an upper waterproof layer and a lower waterproof layer are arranged on the upper surface of the quantum layer and the lower surface of the quantum layer respectively; and the quantum dot layer includes adhesives, silicon gel particles of which the surface is provided with a micropore structure, diffusion particles and quantum dots. It improves the quantum dot utilization by light refraction in the micropore of the silicon gel particles.

Patent document CN204062680U discloses a backlight module provided with quantum dot packaging tube and a display device thereof, wherein the backlight module includes an LED lamp bar, a quantum dot packaging tube, a quantum dot packaging tube clamping device and a light guide plate. In the patented technology, the quantum dot packaging tube clamping device is used to fix the quantum dot packaging tube firmly and stably in the backlight module light source to convert the blue light into white light, thereby improving light utilization efficiency and preventing blue light leakage.

Patent document CN104566015A discloses a quantum dot backlight module, including a light emitting diode, a reflection sheet, a light guide plate, a plurality of screen dots and quantum dots, wherein the screen dots are arranged at intervals to package the quantum dot materials therein, thereby reducing the consumption of the quantum dot material and lowering cost in achieving a light source with high color gamut.

Patent document CN204300782U discloses a side-incident LED Backlight source, including a lower cover, a reflective film, a light guide plate, a first diffusion film, a first brightness enhancement film, a second diffusion film, a second brightness enhancement film, a mullion, a heat dissipation aluminum base and a light bar, wherein the light bar includes a substrate, a blue LED chip and an LED lens, the blue LED chip is used to convert the blue right into white light in corporation with the filter film, the quantum dot phosphor layer and the light adjusting layer, thereby improving color effect and lowering light loss.

Although the above patent documents have disclosed multiple quantum dot films or backlight modules manufactured using the quantum dot technology, a blue LED chip or a blue-green LED chip (GaN or InAs) is used in the above patent documents to excite the packaging file or tube of quantum dots with different sizes, thus there still exits following problems.

First, when the backlight module uses a quantum dot packaging tube, a distance between the LED blue light source and the light guide plate is increased, and the size of the quantum dot bar is increased, which goes against the design to the narrow bezel; in addition, the coupling angle of the light guide plate to the light source is not large enough, extraction efficiency of the light guide plate goes down.

Second, when the backlight module uses a quantum dot film, in order to improve light utilization rate, more diffusion particles may be added into the film to increase optical path through which the rays pass through the quantum dot by increasing light scattering. Since more light scattering may directly increase light loss, which goes against thinness design. In addition, due to water and oxygen sensitivity of the quantum dot, the film may include a water and oxygen isolation layer and a sealed margin packaging (marginal zone), which goes against design of narrow bezel.

Based on the above analysis, the best means of packaging the quantum dot is directly packaging in LED. But the current quantum dot has poor thermal stability, and the photoluminescence thermal decay gets heavily, which impedes the application of quantum dot packaged in LED, thus it is necessary to make improvement to the current quantum dot and the backlight technology thereof, to thereby improve light extraction efficiency and thermal stability of quantum dot.

### SUMMARY

An object of the present disclosure is to provide a metal-doped quantum dot and a LED device and a backlight module prepared using the same, thereby solving the problem that it is not appropriate to package the quantum dot in the LED chip for its poor thermal stability and low photoluminescence efficiency.

Specifically, the present disclosure includes the following four aspects:

[Subject: quantum dot] In a first aspect, the present disclosure provides a metal-doped quantum dot, including an intrinsic quantum dot and a doped metal, wherein the intrinsic quantum dot is composed by any two or more of IB group element, IIB group element, IIIA group element, VA group element or VIA group element, and the doped metal may be one or more of IB group element, VIII group element or VIB group element.

[Quantum dot-concrete compositions] Further, the intrinsic quantum dot may be one or more compounds of CdSe, ZnS, ZnSe or CuInS, and the doped metal may be one or more of Ag, Cr, Ni or Cu. For example, if the intrinsic quantum dot was ZnSe, the ZnSe quantum dot is doped with Cu; or if the intrinsic quantum dot was CdSe, the CdSe quantum dot is doped with Ag; or if the intrinsic quantum dot is CuInS, the CuInS quantum dot is doped with Cr.

[Quantum dot-content of the doped metal] Further, in the quantum dot of the doped metal, the content of the doped metal is 2-8%, and the content range includes any concrete values within 2-8%, such as 3%, 4%, 5%, 6%, 7% or 8%. Preferably, the content of the doped metal is 5%.

[Subject-preparation method] In a second aspect, the present disclosure also provides a method of preparing the above metal-doped quantum dot, including:

preparing an intrinsic quantum dot and a metal to be doped; and

injecting the doped metal into the intrinsic quantum dot under conditions of heating reflux and stirring, to form the metal-doped quantum dot.

[Heating temperature] Further, the temperature of heating reflux is within 140-180° C., the temperature range covers any concrete values therein, such as 140° C., 150° C., 160° C., 170° C. or 180° C.

Preferably, the temperature of heating reflux is 160° C.

[Stirring time] Further, the stirring time is within 5-10 hours. The time range covers any points therein, such as 5 h, 6 h, 7 h, 8 h, 9 h or 10 h. Preferably, the stirring time is 7.5 h.

[Subject: LED device] In a third aspect, the present disclosure provides a LED device, including a positive electrode, a negative electrode and a quantum dot dielectric layer interposed between the positive electrode and the negative electrode, wherein the quantum dot dielectric layer is made of quantum dots of the doped metal.

[Types of the dielectric layer] Further, the quantum dot dielectric layer includes a blue light quantum dot dielectric layer, a green light quantum dot dielectric layer and a red light quantum dot dielectric layer.

[Sequence of the color layers] Further, the blue light quantum dot dielectric layer, the green light quantum dot dielectric layer and the red light quantum dot dielectric layer are sequentially arranged between the negative electrode and the positive electrode, so that both sides of the blue light quantum dot dielectric layer respectively contact the negative electrode and the green light quantum dot dielectric layer, and both sides of the red light quantum dot dielectric layer respectively contact the positive electrode and the green light quantum dot dielectric layer.

[Thickness of the color layers] Further, the blue light quantum dot dielectric layer has a thickness within 1-5 μm, the thickness range covers any concrete values or value range within 1-5 μm, such as 1 μm, 2 μm, 2.5 μm, 3 μm, 4 μm or 5 μm. Preferably, the thickness of the blue light quantum dot dielectric layer is 3 μm; the green light quantum dot dielectric layer has a thickness within 1-5 μm, the thickness range covers any concrete value within 1-5 μm, such as 1 μm, 2 μm, 2.5 μm, 3 μm, 4 μm or 5 μm. Preferably, the thickness of the green light quantum dot dielectric layer is 2 μm; and the red light quantum dot dielectric layer has a thickness within 1-5 μm, the thickness range covers any concrete value within 1-5 μm, such as 1 μm, 1.5 μm, 2 μm, 2.5 μm, 3 μm, 4 μm or 5 μm. Preferably, the thickness of the red light quantum dot dielectric layer is 2 μm.

[Details of the red dielectric layer] Further, the red light quantum dot dielectric layer includes ZnSe quantum dot doped with Cu, and the particle size of the ZnSe quantum dot doped with Cu is about 18-25 nm, the particle size range covers any concrete value within 18-25 nm, such as 18 nm, 19 nm, 20 nm, 21 nm, 22 nm, 23 nm, 24 nm or 25 nm. Preferably, the particle size is 23 nm.

[Details of the green dielectric layer] Further, the green light quantum dot dielectric layer includes the ZnSe quantum dot doped with Cu, the particle size of the ZnSe quantum dot doped with Cu is about 12-20 nm, the particle size range covers any concrete value within 12-20 nm, such as 12 nm, 13 nm, 14 nm, 15 nm, 16 nm or 17 nm. Preferably, the particle size is 17 nm.

[Details of the blue dielectric layer] Further, the blue light quantum dot dielectric layer includes the ZnSe quantum dot doped with Cu, the particle size of the ZnSe quantum dot doped with Cu is about 8-12 nm, the particle size range covers any concrete value within 8-12 nm, such as 8 nm, 9 nm, 10 nm, 11 nm or 12 nm. Preferably, the particle size is 11 nm.

[Positive electrode and negative electrode] Further, the positive electrode and/or the negative electrode is one or more of Ag electrode, Al electrode or ITO electrode.

[Method of preparing the LED device] Further, the LED device is prepared by evaporation or ink-jetting, the negative electrode, the blue light quantum dot dielectric layer, the green light quantum dot dielectric layer, the red light quantum dielectric layer and the positive electrode are sequentially stacked through evaporation or ink-jetting, to thereby obtain the LED device.

[Subject-backlight module] In a fourth aspect, the present disclosure provides a backlight module, including a light guide plate, a LED bar disposed at an edge of one side of the light guide plate, an optical film above the light guide plate and a reflective sheet under the light guide plate, wherein the LED bar include several LED devices.

[Arrangement of the LED devices] Further, the LED bar also includes a frame to fix the LED devices, and the frame is strip shaped to allow the several LED devices to be arranged along the length direction of the frame, and the frame has a width greater than that of any one of the LED devices to receive the LED device.

[Side-incident] Further, the backlight module is a side-incident backlight module.

Compared with the prior art, the advantages of the present disclosure are as follows.

(1) In the present disclosure, a new quantum dot material is obtained by doping metal in the quantum dot, and the quantum dot material has good property of not being quenched at a high temperature, thereby overcoming the defects of bad thermal stability and low electroluminescent efficiency on the existing quantum dot.

(2) In the present disclosure, quantum dot dielectric layers with different colors are prepared respectively. Since these quantum dot dielectric layers have good thermal stability, the layers can be packaged together to form a new-type quantum dot LED, which can emit white light by mixing red, green and blue light to achieve presence of high color gamut.

(3) The present disclosure breaks the limitation that the existing backlight module needs to package a quantum dot film or a package tube separately except the blue or blue-green LED chip, thereby overcoming the difficulty of applying the quantum dot technique in the small-to-medium-size display screen. Since the quantum dot dielectric layer of different colors can be packaged in a LED by means of the technique in the present invention, the LED device is enabled to be arranged in the backlight module according to the simple strip layout. The structure is simple and adapt for the side-incident backlight module, thus the display device can be made thinner and narrower, such that the ultra-thin and narrow bezel product can be designed having a comparative large space.

### BRIEF DESCRIPTION OF THE DRAWINGS

FIG. 1 is a comparison diagram of temperature decay testing of the ZnSe quantum dot not doped with metal and the ZnSe quantum dot doped with metal in the present invention.

FIG. 2 is a structural diagram of the LED device provided in embodiment 10.

FIG. 3 is a structural diagram of the LED device provided in embodiment 12.

FIG. 4 is a structural diagram of the LED bar provided in embodiment 12.

### DETAILED DESCRIPTION OF EXEMPLARY EMBODIMENTS

Below, the present disclosure will be explained in details according to detailed embodiments. It should be understood that, these detailed exemplary embodiments are only used to illustrate the present invention, but not make any limitation of any forms to the actual protection scope of the present invention.

### Embodiment 1

The present embodiment provides a metal-doped quantum dot, which is prepared as follows:

preparing an intrinsic quantum dot, i.e., ZnSe quantum dot; and

injecting copper ions as metal element into the ZnSe quantum dot at 160° C., constantly stirring and heating for 5 hours, thereby forming the ZnSe quantum dot doped with copper ions (which is named Q-1), in which the content of the doped copper ions is about 5%.

The quantum dot is a blue light quantum dot and has a particle size of 11 nm.

### Embodiment 2

The present embodiment provides a metal-doped quantum dot, which is prepared as follows:

preparing an intrinsic quantum dot, i.e., ZnSe quantum dot; and

injecting copper ions as metal element into the ZnSe quantum dot at 140° C., constantly stirring and heating for 10 hours, thereby forming the ZnSe quantum dot doped with copper ions (which is named Q-2), in which the content of the doped copper ions is about 3%.

The quantum dot is a blue light quantum dot and has a particle size of 8 nm.

### Embodiment 3

The present embodiment provides a metal-doped quantum dot, which is prepared as follows:

preparing an intrinsic quantum dot, i.e., ZnSe quantum dot; and

injecting copper ions as metal element into the ZnSe quantum dot at 180° C., constantly stirring and heating for 7.5 hours, thereby forming the ZnSe quantum dot doped with copper ions (which is named Q-3), in which the content of the doped copper ions is about 8%.

The quantum dot is a blue light quantum dot and has a particle size of 12 nm.

### Embodiment 4

The present embodiment provides a metal-doped quantum dot, which is prepared as follows:

preparing an intrinsic quantum dot, i.e., ZnSe quantum dot; and

injecting copper ions as metal element into the ZnSe quantum dot at 160° C., constantly stirring and heating for 7.5 hours, thereby forming the ZnSe quantum dot doped with copper ions (which is named Q-4), in which the content of the doped copper ions is about 5%.

The quantum dot is a green light quantum dot and has a particle size of 17 nm.

### Embodiment 5

The present embodiment provides a metal-doped quantum dot, which is prepared as follows:

preparing an intrinsic quantum dot, i.e., ZnSe quantum dot; and

injecting copper ions as metal element into the ZnSe quantum dot at 140° C., constantly stirring and heating for 10 hours, thereby forming the ZnSe quantum dot doped with copper ions (which is named Q-5), in which the content of the doped copper ions is about 4%.

The quantum dot is a green light quantum dot and has a particle size of 12 nm.

### Embodiment 6

The present embodiment provides a metal-doped quantum dot, which is prepared as follows:

preparing an intrinsic quantum dot, i.e., ZnSe quantum dot; and

injecting copper ions as metal element into the ZnSe quantum dot at 180° C., constantly stirring and heating for 7.5 hours, thereby forming the ZnSe quantum dot doped with copper ions (which is named Q-6), in which the content of the doped copper ions is about 7%.

The quantum dot is a green light quantum dot and has a particle size of 20 nm.

### Embodiment 7

The present embodiment provides a metal-doped quantum dot, which is prepared as follows:

preparing an intrinsic quantum dot, i.e., ZnSe quantum dot; and

injecting copper ions as metal element into the ZnSe quantum dot at 160° C., constantly stirring and heating for 10 hours, thereby forming the ZnSe quantum dot doped with copper ions (which is named Q-7), in which the content of the doped copper ions is about 5%.

The quantum dot is a red light quantum dot and has a particle size of 23 nm.

### Embodiment 8

The present embodiment provides a metal-doped quantum dot, which is prepared as follows:

preparing an intrinsic quantum dot, i.e., ZnSe quantum dot; and

injecting copper ions as metal element into the ZnSe quantum dot at 150° C., constantly stirring and heating for 9 hours, thereby forming the ZnSe quantum dot doped with copper ions (which is named Q-8), in which the content of the doped copper ions is about 4%.

The quantum dot is a red light quantum dot and has a particle size of 18 nm.

### Embodiment 9

The present embodiment provides a metal-doped quantum dot, which is prepared as follows:

preparing an intrinsic quantum dot, i.e., ZnSe quantum dot; and

injecting copper ions as metal element into the ZnSe quantum dot at 180° C., constantly stirring and heating for 8 hours, thereby forming the ZnSe quantum dot doped with copper ions (which is named Q-9), in which the content of the doped copper ions is about 7%.

The quantum dot is a red light quantum dot and has a particle size of 25 nm.

Performance Testing Experiments

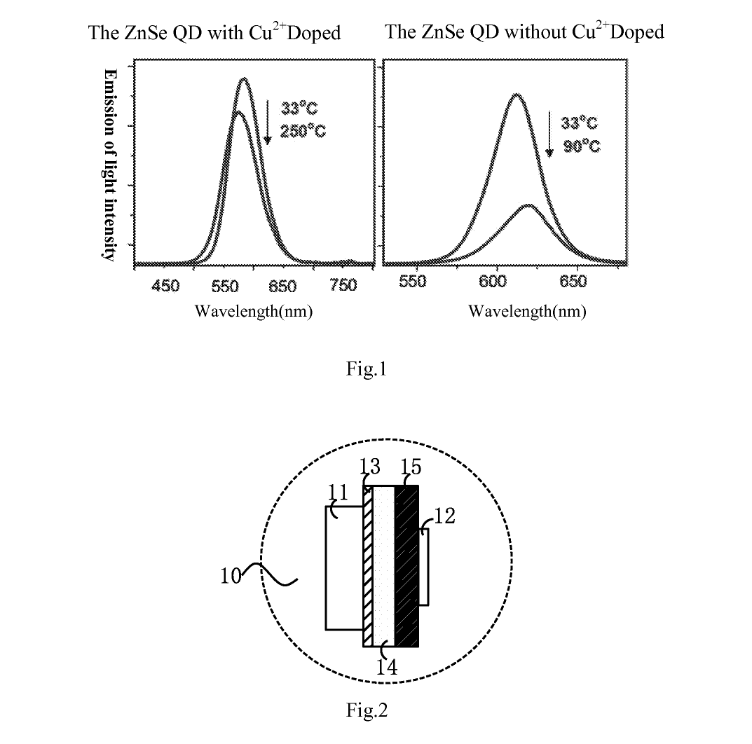

As for the ZnSe quantum dot not doped with a metal, a temperature decay test is performed to respective ZnSe quantum dot doped with copper ions prepared in the embodiments 1-9, the result is shown in FIG. 1.

As shown in FIG. 1, luminescence decay of the ZnSe quantum dot not doped with a metal gets obvious with the temperature raises, but luminescence decay of the ZnSe quantum dot doped with copper ions is not obvious when the temperature rises, that means the ZnSe quantum dot doped with copper ions has good thermal stability, i.e., the metal-doped quantum dot has good thermal stability and may not be easily quenched at high temperature.

### Embodiment 10

The present embodiment discloses a LED device, as shown in FIG. 2, the LED device includes an ITO negative electrode 11 disposed on the left side, a sliver positive electrode 12 disposed on the right side and quantum dot dielectric layers disposed therebetween. These quantum dot dielectric layers are a blue light quantum dot dielectric layer 13 having a thickness of 3 um, a green light quantum dot dielectric layer 14 having a thickness of 2 um and a red light quantum dot dielectric layer 15 having a thickness of 2 um disposed in a sequence from left to right, where the left side of the light quantum dot dielectric layer 13 contacts the ITO negative electrode, the right side of the blue light quantum dot dielectric layer 13 contacts the green light quantum dot dielectric layer 14, the right side of the green quantum dielectric layer 14 contacts the left the side of the red light quantum dot dielectric layer 15, and the right side of the red quantum dot dielectric layer 15 contacts the metal positive electrode 12.

It can be understood that the blue light quantum dot dielectric layer in the present embodiment is composed of the blue quantum dots in embodiment 1, the green light quantum dot dielectric layer is composed of the green light quantum dots in embodiment 4, and the red light quantum dot dielectric layer is composed of the red quantum dots in embodiment 7.

In the present embodiment, a LED device is made by means of evaporation technique. In particular, the LED device is manufactured by evaporating and stacking the blue light quantum dot dielectric layer, the green light quantum dot dielectric layer, the red light quantum dot dielectric layer and the sliver positive electrode sequentially on the ITO negative electrode. Further, evaporation technique is a conventional technique, thus is not illustrated herein.

### Embodiment 11

Embodiment 11 differs from embodiment 10 only in that the thickness of the blue light quantum dot dielectric layer is 2 μm, the thickness of the green light quantum dot dielectric layer is 1 μm, and the thickness of the red light quantum dot dielectric layer is 1 μm according to the present embodiment.

### Embodiment 12

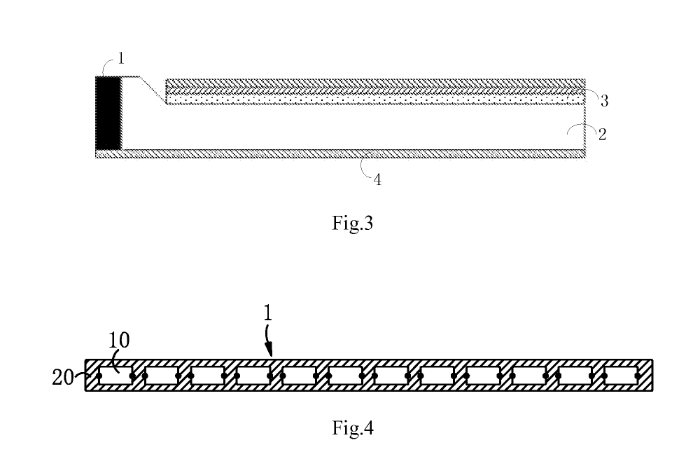

The present embodiment provides a side-incident backlight module. As shown in FIG. 3, the side-incident module includes a light guide plate 2, a LED bar 1 disposed on the left side of the light guide plate 2, an optical film 3 disposed above the light guide plate 2 and a reflective sheet 4 disposed under the light guide plate.

As shown in FIG. 4, the LED bar 1 includes several LED devices 10 and a frame 20 for fixing the LED devices. The frame 20 is strip shaped to allow the several LED devices 10 to be arranged therein along the length direction of the frame 20 (left-right direction shown in FIG. 4), and the width of the frame 20 (up-down direction shown in FIG. 2) is greater than that of the LED device, such that several LED devices can be arranged in a line in the frame exactly. On can understand that, the LED device in the present embodiment is the LED device prepared in embodiment 4, and the number of the LED bars can be determined according demand of the backlight module, thus the number of the LED devices may be 12 as shown in FIG. 4, or other numbers.

The above embodiments in the present disclosure are enumerated to explain the present disclosure clearly, but not limitation to the embodiments in the present invention. To those ordinary skilled in the art, any other change or variation in different forms can also be made based on the above explanation. Here, it cannot or do not have to make an exhaustion to all embodiments. Any amendments, equivalent placement and improvement made within the spirit and principle of the present disclosure should be included in the protection scope of the claims of the present invention.

1. A metal-doped quantum dot, comprising: an intrinsic quantum dot made of any two or more of IB group element, IIB group element, IIIA group element, VA group element and VIA group element, and a doped metal which is one or more of IB group element, VIII group element and VIB group element.

2. The metal-doped quantum dot of claim 1, wherein the intrinsic quantum dot is one or more of CdSe, ZnS, ZnSe or CuInS, and the doped metal is one or more of Ag, Cr, Ni or Cu.

3. The metal-doped quantum dot of claim 1, wherein the content of the doped metal in the metal-doped quantum dot is 2-8%.

4. The metal-doped quantum dot of claim 2, wherein the content of the doped metal in the metal-doped quantum dot is 2-8%.

5. A method of preparing the metal-doped quantum dot of claim 1, comprising:
preparing an intrinsic quantum dot and a metal to be doped;
injecting the doped metal into the intrinsic quantum dot under conditions of heating reflux and stirring, to form the metal-doped quantum dot.

6. A method of preparing the metal-doped quantum dot of claim 2, comprising:
preparing an intrinsic quantum dot and a metal to be doped;
injecting the doped metal into the intrinsic quantum dot under conditions of heating reflux and stirring, to form the metal-doped quantum dot.

7. A method of preparing the metal-doped quantum dot of claim 3, comprising:
preparing an intrinsic quantum dot and a metal to be doped;
injecting the doped metal into the intrinsic quantum dot under conditions of heating reflux and stirring, to form the metal-doped quantum dot.

8. A LED device, comprises a positive electrode and a negative electrode, wherein the LED device further comprises a quantum dot dielectric layer disposed between the positive electrode and the negative electrode, and the quantum dot dielectric layer comprises a metal doped quantum dot, wherein the metal-doped quantum dot comprises an intrinsic quantum dot made of any two or more of IB group element, IIB group element, IIIA group element, VA group element or VIA group element, and a doped metal which is one or more of IB group element, VIII group element or VIB group element.

9. The LED device of claim 8, wherein the quantum dot dielectric layer includes a blue light quantum dot dielectric layer, a green light quantum dot dielectric layer and a red light quantum dot dielectric layer.

10. The LED device of claim 9, wherein the blue light quantum dot dielectric layer, the green light quantum dot dielectric layer and the red light quantum dot dielectric layer are sequentially disposed from the negative electrode to the positive electrode, such that both sides of the blue light quantum dot dielectric layer contact the negative electrode and the green light quantum dot dielectric layer, respectively; and both sides of the red light quantum dot dielectric layer contact the positive electrode and the green light quantum dot dielectric layer, respectively.

11. A backlight module, comprises: a light guide plate, a LED bar disposed at an edge side of the light guide plate, an optical film disposed above the light guide plate and a reflective sheet disposed under the light guide plate, wherein the LED bar comprises a LED device comprising a positive electrode, a negative electrode and a quantum dot dielectric layer disposed between the negative electrode and the positive electrode, and the quantum dot dielectric layer comprises an intrinsic quantum dot which is made of any two or more of IB group element, IIB group element, IIIA group element, VA group element or VIA group element, and a doped metal which is one or more of IB group element, VIII group element or VIB group element.

12. The backlight module of claim 11, wherein the LED bar further comprises a frame for fixing the LED device, and the LED bar is strip shaped to allow the several LED devices to be arranged along the length direction of the frame, and the width of the frame is greater than the width of any of the LED devices to receive the LED device.

13. The backlight module of claim 12, wherein the backlight module is a side-incident backlight module.
